(19) United States
(12) Patent Application Publication
(10) Pub. No.: US 2024/0370043 A1
(43) Pub. Date: Nov. 7, 2024

(54) MASS FLOW CONTROLLER AND ZERO POINT CALIBRATION METHOD USING THE SAME

(71) Applicant: Samsung Electronics Co., Ltd., Suwon-si (KR)

(72) Inventors: Seunghun Kim, Suwon-si (KR); Minjung Kim, Suwon-si (KR); Taemin Kim, Suwon-si (KR); Jiho Uh, Suwon-si (KR); Jinseok Lee, Suwon-si (KR); Geongu Jang, Suwon-si (KR)

(21) Appl. No.: 18/652,866

(22) Filed: May 2, 2024

(30) Foreign Application Priority Data
May 4, 2023 (KR) 10-2023-0058768
Jun. 27, 2023 (KR) 10-2023-0082884

(51) Int. Cl. G05D 7/06; H01L 21/67

(52) U.S. Cl. CPC G05D 7/0623; H01L 21/67017

(57) ABSTRACT

A method of manufacturing using a mass flow controller (MFC) includes closing a valve installed in a flow path of the MFC to prevent a fluid from flowing therein due to a closure of the valve, determining that the fluid is not leaking, determining that the fluid is stabilized, determining that a pressure sensor is normal, calculating a zero point calibration value of the pressure sensor based on a zero point of the pressure sensor, a time when power is supplied to the MFC, and a time when a flow is supplied to the MFC, applying the zero point calibration value to the pressure sensor, and measure the mass flow rate through the flow path with the pressuring sensor and adjusting the valve based on the mass flow rate to regulate the flow of the fluid to a manufacturing device.

### CROSS-REFERENCE TO RELATED APPLICATION

This application is based on and claims priority under 35 U.S.C. § 119 to Korean Patent Application Nos. 10-2023-0058768, filed on May 4, 2023, and 10-2023-0082884, filed on Jun. 27, 2023, in the Korean Intellectual Property Office, the disclosures of which are incorporated by reference herein in their entireties.

### BACKGROUND

The inventive concept relates to the manufacture of semiconductor devices using a semiconductor process that uses a mass flow controller (MFC) to provide a controlled mass of a fluid and a zero point calibration method for the MFC.

MFCs are used to measure and control the flowrate of a gas fluid supplied to a process chamber during a semiconductor manufacturing process. MFCs control the flow rate of a gas fluid to accurately supply the gas fluid within a controlled range to enhance the resultant of the semiconductor manufacturing process.

### SUMMARY

The inventive concept provides a mass flow controller (MFC) capable of accurately measuring the flow of a fluid and improving the quality of a manufacturing process by precisely supplying the fluid to the manufacturing process, and a manufacturing process using the zero point calibration method to calibrate the zero point.

technical idea of the inventive concept is not limited to solving the problems mentioned above, and other problems not mentioned but will be clearly understood by those skilled in the art from the description below.

According to an aspect of the inventive concept, there is provided a method of manufacturing using a mass flow controller (MFC) including closing a valve installed in a flow path of the MFC to prevent a fluid from flowing therein due to a closure of the flow path, determining that the fluid is not leaking based on a first pressure value output by a first pressure sensor provided in the flow path and a second pressure value output by a second pressure sensor provided in the flow path, determining that the fluid is stabilized based on the first pressure value and the second pressure value, determining that the first pressure sensor and the second pressure sensor are normal based on a difference between the first pressure value and the second pressure value, calculating a first zero point calibration value for the first pressure sensor and a second zero point calibration value for the second pressure sensor based on a first zero point of the first pressure sensor and a second zero point of the second pressure sensor, a time when power is supplied to the MFC, and a time when a flow is supplied to the MFC, applying the first zero point calibration value to a zero point of the first pressure sensor and the second zero point calibration value to a zero point of the second pressure sensor, and measuring the mass flow rate through the flow path with the first pressure sensor and the second pressure sensor and adjusting the valve based on the mass flow rate to regulate the flow of the fluid to a manufacturing device.

According to another aspect of the inventive concept, there is provided a zero point calibration method of an MFC including closing a valve installed in a flow path of the MFC to prevent a fluid from flowing due to a closure of the valve, determining whether the fluid is leaking by determining whether a rate of change of a first pressure value over time and a rate of change of a second pressure value over time are less than or equal to a predetermined threshold value, based on the first pressure value output by a first pressure sensor provided in the flow path and the second pressure value output by a second pressure sensor provided in the flow path, determining that the fluid is stabilized by determining that a standard deviation of the first pressure value and a standard deviation of the second pressure value are less than or equal to a predetermined threshold value based on the first pressure value and the second pressure value, determining that the first pressure sensor and the second pressure sensor are normal based on a difference between the first pressure value and the second pressure value, calculating a first zero point calibration value for the first pressure sensor and a second zero point calibration value for the second pressure sensor, applying the first zero point calibration value to a first zero point of the first pressure sensor and applying the second zero point calibration value to a second zero point of the second pressure sensor, and measuring the mass flow rate through the flow path with the first pressure sensor and the second pressure sensor and adjusting the valve based on the mass flow rate to regulate the flow of the fluid to a manufacturing device.

According to another aspect of the inventive concept, there is provided a method of manufacturing using a MFC including closing a valve installed in a flow path of the MFC to prevent a fluid from flowing therein due to a closure of the flow path, determining that the fluid is not leaking by determining that a change rate of each of a first pressure value and a second pressure value over time are less than or equal to a predetermined threshold value, based on the first pressure value output by a first pressure sensor provided in the flow path and the second pressure value output by a second pressure sensor provided in the flow path, determining whether the fluid is stabilized by determining whether a standard deviation of the first pressure value and a standard deviation of the second pressure value are less than or equal to a predetermined threshold value, determining whether the first pressure sensor and the second pressure sensor are normal by determining whether a difference between the first pressure value and the second pressure value is less than or equal to a predetermined threshold, calculating a respective zero point calibration value of each of the first pressure sensor and the second pressure sensor based on a respective zero point of each of the first pressure sensor and the second pressure sensor, a time when power is supplied to the MFC, and a time when a flow is supplied to the MFC, and applying the respective zero point calibration value to the respective zero point of each of the first pressure sensor and the second pressure sensor, wherein the respective zero point calibration value is obtained by adding a value obtained by multiplying the time when the power is supplied to the MFC by a respective first coefficient to a value obtained by multiplying the time when the flow is supplied to the MFC by a respective second coefficient, and after applying the respective zero point calibration value, the zero point calibration method is repeated from the determining whether the fluid is leaking, and, when a number of times the respective zero point calibration value has been applied is N times or more (N is a natural number of 1 or more) in the applying of the respective zero point calibration value, the zero point calibration ends.

### BRIEF DESCRIPTION OF THE DRAWINGS

Embodiments will be more clearly understood from the following detailed description taken in conjunction with the accompanying drawings in which:

FIG. 1 is a schematic diagram illustrating a mass flow controller (MFC) according to an embodiment;

FIG. 2 is a flowchart illustrating a zero point calibration method used by the MFC according to an embodiment;

FIG. 3 is a flowchart illustrating a zero point calibration method for the pressure sensors of the MFC according to an embodiment;

FIG. 4 is a flowchart illustrating a zero point calibration method for the pressure sensors of the MFC according to an embodiment;

FIG. 5 is a flowchart illustrating a zero point calibration method for the pressure sensors of the MFC according to an embodiment;

FIG. 6 is a flowchart illustrating a zero point calibration method used for the pressure sensors of the MFC according to an embodiment;

FIG. 7 is a flowchart illustrating a zero point calibration method used for the pressure sensors of the MFC according to an embodiment;

FIG. 8 is a graph illustrating a simulation of performing a zero point calibration method used by an MFC according to an embodiment; and

FIG. 9 is a graph illustrating results of applying a zero point calibration method used by an MFC in a facility according to an embodiment.

### DETAILED DESCRIPTION OF THE EMBODIMENTS

Hereinafter, embodiments are described with reference to the accompanying drawings. In the drawings, like reference numerals denote like elements, and redundant descriptions thereof may be omitted.

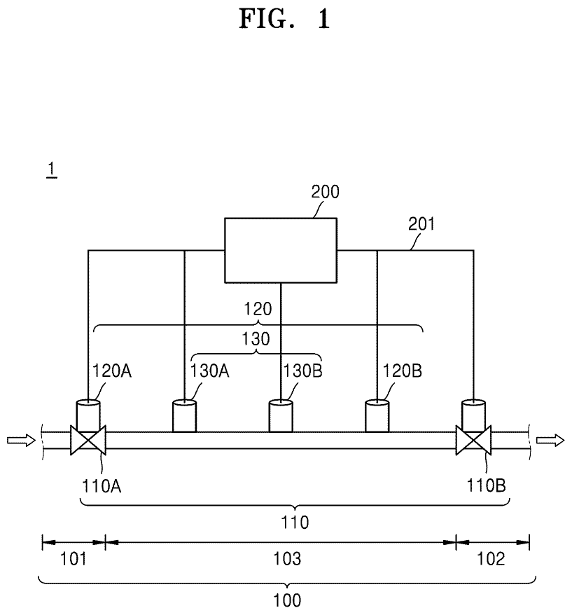

FIG. 1 is a diagram schematically illustrating a mass flow controller (MFC) 1 according to an embodiment.

Referring to FIG. 1, the MFC 1 according to an embodiment may include a flow path 100, a valve unit 110, a sensor unit 130, and a controller 200.

The flow path 100 may be an internal passage of the MFC 1 through which fluid may flow. The flow path 100 may include an inlet flow path portion 101, an outlet flow path portion 102, and a main flow path portion 103 between the inlet flow path portion 101 and the outlet flow path portion 102.

The valve unit 110 may include at least one valve. The at least one valve may be provided inside the MFC 1. The valve unit 110 may include, for example, a first valve 110A and a second valve 110B. The first valve 110A may be provided in the inlet flow path portion 101, and the second valve 110B may be provided in the outlet flow path portion 102. In FIG. 1, the valve unit 110 is shown as including a valve on each of the inlet flow path portion 101 and the outlet flow path portion 102, but the embodiments are not limited thereto, and a valve may be provided on only one of the inlet flow path portion 101 and the outlet flow path portion 102 in some embodiments.

The sensor unit 130 may include a first pressure sensor 130A and a second pressure sensor 130B. The first pressure sensor 130A and the second pressure sensor 130B may each output a pressure value (e.g., a digital representation or an analog signal level) that corresponds to the pressure measured by the respective pressure sensor. The first pressure sensor 130A may be provided in the main flow path portion 103 and configured to measure the pressure in the main flow path portion 103 near the inlet flow path portion 101, and the second pressure sensor 130B may be provided in the main flow path portion 103 and configured to measure the pressure in the main flow path portion 103 near the outlet flow path portion 102. For example, the first pressure sensor 130A and the second pressure sensor 130B may be provided at opposing ends of the main flow path portion 103.

In an embodiment, the MFC 1 may be configured to control the flow rate for a gas fluid. The MFC 1 may be configured to measure and control a flow of the gas fluid as it is supplied to a semiconductor manufacturing device where the fluid is used in manufacturing a semiconductor device. Examples of semiconductor manufacturing devices include devices that perform semiconductor manufacturing processes such as an exposure process, a development process, an etching process, or a cleaning process and the subsequent steps in manufacturing the semiconductor device may include exposure, development (e.g., the fluid is a developer to develop a pattern of an exposed photoresist which is then used for etching a layer of a wafer from which the semiconductor device is being formed), etching (e.g., the fluid is an etchant to etch a layer of the wafer) and/or cleaning process(es) (e.g., the fluid is a cleaning fluid to clean the wafer). The type of the semiconductor manufacturing processes performed by the semiconductor manufacturing device in the embodiments is not limited to these examples and in other examples a semiconductor manufacturing device may use the described MFC to perform other types of semiconductor manufacturing processes that use a regulated flow of gas.

MFCs may be largely classified into a thermal type MFC and a differential pressure type MFC. The MFC 1 according to an embodiment is described as being a differential pressure type MFC, but the inventive concept is not limited thereto. The inventive concept may also be applied to a fluid mass meter and a controller that controls the mass flow of a fluid in a differential pressure manner. The inventive concept may also be similarly applied to a fluid mass meter that does not include a valve inside the fluid mass meter through a control signal from a valve of a controller interworking with the fluid mass meter.

As shown in FIG. 1, a fluid may be introduced into the flow path 100 of the MFC 1 through the inlet flow path portion 101. The fluid may pass from the inlet flow path portion 101 through the main flow path portion 103 to the outlet flow path portion 102. The fluid may exit the flow path 100 of the MFC 1 through the inlet flow path portion 101 and the outlet flow path portion 102.

The first valve 110A may be provided in the inlet flow path portion 101, and the second valve 110B may be provided in the outlet flow path portion 102. The first valve 110A and/or the second valve 110B may be provided inside the MFC 1. The first valve 110A and the second valve 110B may be configured to be manually or automatically opened and closed. In an embodiment, the first valve 110A and the second valve 110B may be automatically opened and closed by an actuator 120, which may be provided in the valve unit 110. For example, a first actuator 120A opening and closing the first valve 110A may be provided in the first valve 110A. A second actuator 120B opening and closing the second valve 110B may be provided in the second valve 110B. The first and second actuators 120A and 120B may be motors (e.g., servomotors). The first actuator 120A and the second actuator 120B may respectively provide a rotational force (i.e., torque) to the first valve 110A and the second valve 110B which may open or close the first valve 110A and/or the second valve 110B. The configurations of the first actuator 120A, the second actuator 120B, the first valve 110A, and the second valve 110B are not limited thereto and may be different in other embodiments. In some embodiments, at least one of the configurations of the first actuator 120A, the second actuator 120B, the first valve 110A, and the second valve 110B may be omitted or replaced.

The first actuator 120A and the second actuator 120B may be configured to be operated by the controller 200. The controller 200 may be configured to exchange electrical signals with the first actuator 120A and the second actuator 120B wirelessly and/or by a wired connection. In an embodiment, the first actuator 120A and the second actuator 120B may each be electrically connected to the controller 200 through signal wires 201.

The first pressure sensor 130A and the second pressure sensor 130B may be respectively provided in the main flow path portion 103 between the first valve 110A and the second valve 110B. A laminar flow device may be additionally provided in the main flow path portion 103 between the first valve 110A and the second valve 110B. The first pressure sensor 130A and the second pressure sensor 130B may respectively measure the pressure of a fluid in the main flow path portion 103 at both ends of the main flow path portion 103 between the first valve 110A and the second valve 110B. For example, the first pressure sensor 130A may measure the pressure of the fluid in the main flow path portion 103 on the side nearer to the inlet flow path portion 101, and the second pressure sensor 130B may measure the pressure of the fluid in the main flow path portion 103 on the side nearer to the outlet flow path portion 102.

The first pressure sensor 130A and the second pressure sensor 130B may each be configured to measure the pressure in the main flow path portion 103 at a predetermined time interval as described below. The first pressure sensor 130A and the second pressure sensor 130B may each be connected to the controller 200 by a wired or wireless connection and may each transmit and receive electrical signals with the controller 200 over the wired or wireless connection. In an embodiment, the first pressure sensor 130A and the second pressure sensor 130B may each be electrically connected to the controller 200 through the signal wires 201 and may transmit and receive measured values through the signal wires 201. In an embodiment, the first pressure sensor 130A and the second pressure sensor 130B may be electrically connected to the controller 200 through the signal wires 201 and the controller 200 may be configured to apply zero point calibration values to each of the first pressure sensor 130A and the second pressure sensor 130B.

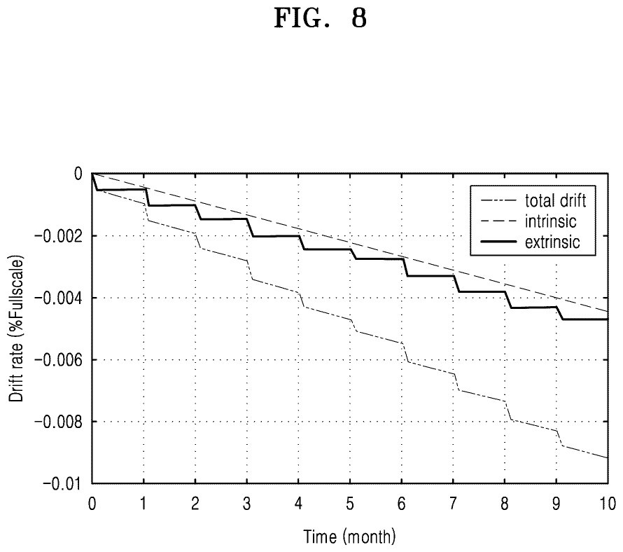

The controller 200 may include a processor and a memory. The processor may execute program commands stored in the memory. The processor may be or may include a central processing unit (CPU), a graphics processing unit (GPU), or a dedicated processor. The processor may implement computer executable instructions that implement the methods according to the inventive concept. The memory may include a volatile storage medium and/or a non-volatile storage medium that stores the computer executable instructions for implementing the methods according to the inventive concept. For example, the memory may include read only memory (ROM) and/or random access memory (RAM). The controller 200 may be configured to correct a zero point of the MFC 1 according to an embodiment by implementing a zero point calibration method for the MFC 1 as described below. The controller 200 may perform the zero point calibration method for the MFC 1 according to an embodiment using pressure values received from the first pressure sensor 130A and the second pressure sensor 130B. The controller 200 may correct a zero point of the first pressure sensor 130A by applying a first electrical signal to the first pressure sensor 130A and may correct a zero point of the second pressure sensor 130B by applying a second electrical signal to the second pressure sensor 130B. The electrical signal may be, for example, a drift signal that will be described below with reference to FIG. 8.

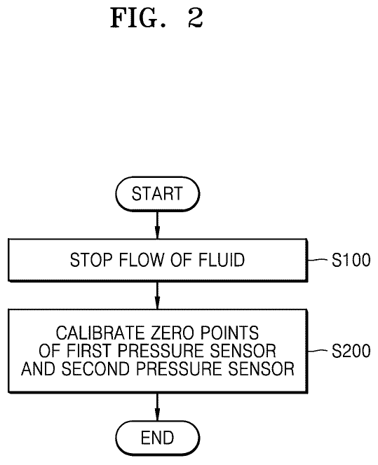

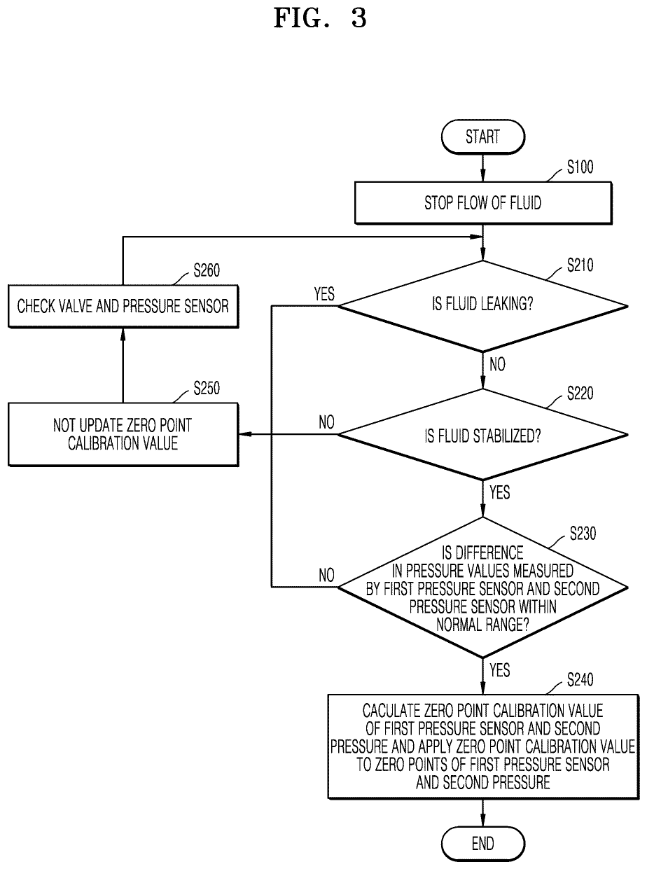

FIG. 2 is a flowchart illustrating a zero point calibration method used by the MFC 1 according to an embodiment. FIG. 3 is a flowchart illustrating a zero point calibration method for the first pressure sensor 130A and the second pressure sensor 130B of the MFC 1 according to an embodiment.

Referring to FIGS. 2 and 3, the zero point calibration method used by the MFC 1 according to an embodiment may include operation S100 of stopping the flow of a fluid in the MFC 1 and operation S200 of correcting the zero points of the first pressure sensor 130A and the second pressure sensor 130B. Correcting the zero point in operation S200 may be based on a pressure value output by the first pressure sensor 130A and/or the second pressure sensor 130B while the flow through the MFC 1 is stopped according to an embodiment.

Operation S100 of stopping the flow of the fluid may include stopping the flow of the fluid in the main flow path portion 103 by closing a valve. According to an embodiment, operation S100 may include stopping the flow of the fluid in the main flow path portion 103 between the first valve 110A and the second valve 110B by closing the first valve 110A and the second valve 110B described above. The first valve 110A and/or the second valve 110B may be closed manually or by an actuator. The controller 200 may send a signal to an actuator to close a valve.

Operation S200 of correcting the zero points of the first pressure sensor 130A and the second pressure sensor 130B may include correcting the zero points of the first pressure sensor 130A and the second pressure sensor 130B based on pressure values output by the first pressure sensor 130A and the second pressure sensor 130B when the flow is stopped. Operation S200 of correcting the zero points of the first pressure sensor 130A and the second pressure sensor 130B is described in more detail below.

Operation S200 of correcting the zero points of the first pressure sensor 130A and the second pressure sensor 130B described above may be performed as shown in FIG. 3. Operation S100 of stopping the flow of the fluid may be the same as operation S100 shown in FIG. 2.

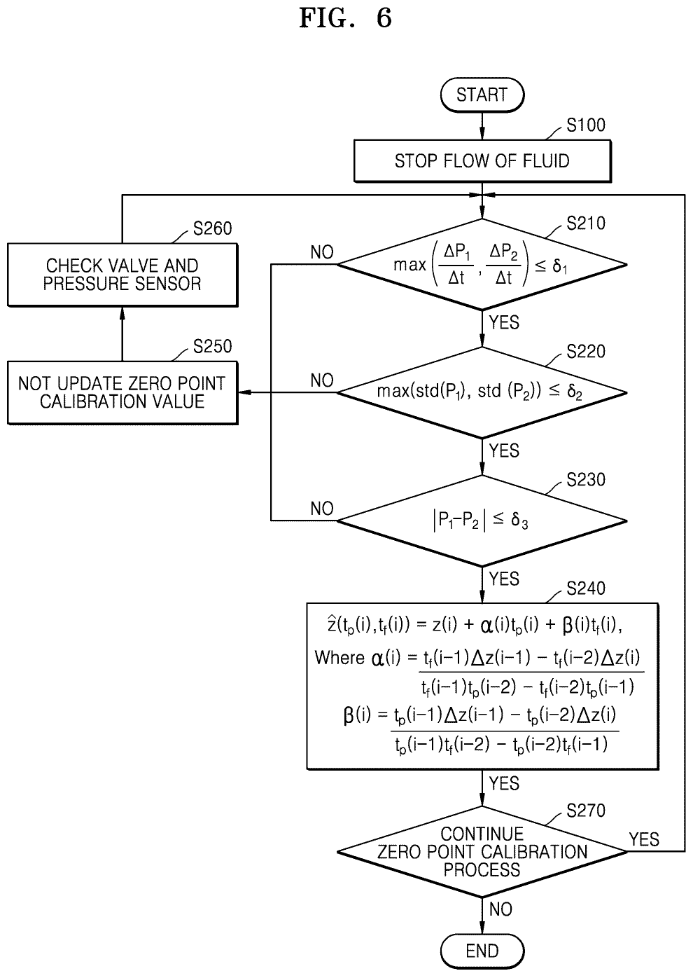

Operation S200 of correcting the zero points of the first pressure sensor 130A and the second pressure sensor 130B may include operation S210 of determining, based on the pressure values output by the first pressure sensor 130A and the second pressure sensor 130B, which are installed in the main flow path portion 103, whether the fluid is leaking from the main flow path portion 103, operation S220 of determining, based on the pressure values output by the first pressure sensor 130A and the second pressure sensor 130B, whether the fluid is stabilized in the main flow path portion 103, operation S230 of determining whether a difference in the pressure values output by the first pressure sensor 130A and the second pressure sensor 130B is within a normal range, and operation S240 of calculating a zero point calibration value for each of the first pressure sensor 130A and the second pressure sensor 130B based on the pressure values output by the first pressure sensor 130A and the second pressure sensor 130B and applying the zero point calibration value of each of the first pressure sensor 130A and the second pressure sensor 130B to the respective zero points of each of the first pressure sensor 130A and the second pressure sensor 130B. FIG. 6 provides exemplary details of operations S310, S320, S330, and S340 that may be implemented with the corresponding operations of the embodiments described elsewhere herein.

As shown in FIG. 6, whether the fluid is leaking from the main flow path portion 103 may be determined in operation S210 based on the rate of change of the pressure within the main flow path portion 103 with respect to time

$$\frac{Δ P}{Δ t} .$$

The rate of change of the pressure

$$\frac{Δ P}{Δ t}$$

within the main flow path portion 103 may be determined based on the pressure values P₁, P₂ output by the first pressure sensor 130A and the second pressure sensor 130B. The rate of change of the pressure value P₁ output by the first pressure sensor 130A may be identified as

$$\frac{Δ {P}_{1}}{Δ t}$$

and the rate of change of the pressure value P₂ by the second pressure sensor 130B identified as

$$\frac{Δ {P}_{2}}{Δ t} .$$

Here, Δt may refer to a time interval between measurements of the pressure, ΔP₁ may refer to a change of the pressure value output by the first pressure sensor 130A during the time interval, and ΔP₂ may refer to a change of the pressure value output by the second pressure sensor 130B during the time interval. The determination of whether the fluid is leaking from the main flow path portion 103 may be based on the maximum of the rate of change of the pressure values

$${( \frac{Δ {P}_{1}}{Δ t} , \frac{Δ {P}_{2}}{Δ t} )}_{max} .$$

More specifically, it may be determined that the fluid is leaking from the main flow path portion 103 based on comparing the maximum of the rate of change of the pressure values

$${( \frac{Δ {P}_{1}}{Δ t} , \frac{Δ {P}_{2}}{Δ t} )}_{max}$$

with a first threshold value δ₁. When the maximum of the rate of change of the pressure values

$${( \frac{Δ {P}_{1}}{Δ t} , \frac{Δ {P}_{2}}{Δ t} )}_{max}$$

is less than the threshold value δₜ it may indicate that the fluid is not leaking, and when the maximum of the rate of change of the pressure values

$${( \frac{Δ {P}_{1}}{Δ t} , \frac{Δ {P}_{2}}{Δ t} )}_{max}$$

is greater than the threshold value δ₁ it may indicate that the fluid is leaking (e.g.,

$${( \frac{Δ {P}_{1}}{Δ t} , \frac{Δ {P}_{2}}{Δ t} )}_{max} \leq {δ}_{1}$$

may indicate that the fluid is not leaking and

$${( \frac{Δ {P}_{1}}{Δ t} , \frac{Δ {P}_{2}}{Δ t} )}_{max} > {δ}_{t}$$

may indicate that the fluid is leaking). When both of the rates of change of the pressure values with respect to time output by the first pressure sensor 130A and the second pressure sensor 130B are less than or equal to the predetermined threshold value δ₁, the change of the pressure of the fluid in the main flow path portion 103 may be relatively small. Therefore, when the rate of change of the pressure values with respect to time are small, it may be determined that the flow of the fluid is stopped and the valve is not leaking since further flow and/or leakage would result in a greater rate of change of the pressure value with respect to time. The threshold value δ₁ may be determined depending on a facility environment of the MFC 1.

When any one of the rates of change of the pressure values with respect to time

$$( \frac{Δ {P}_{1}}{Δ t} , \frac{Δ {P}_{2}}{Δ t} )$$

exceeds the predetermined threshold value δ₁, it may indicate that the flow of the fluid in the main flow path portion 103 is not securely stopped by the valve, and that the valve is leaking.

That is, through operation S210 of determining whether the fluid is leaking from the main flow path portion 103, it may be determined whether the flow of the fluid is stopped by the valve. It may be necessary to stop the flow of the fluid within the main flow path portion 103 correct the zero point of the MFC 1. Thus, before proceeding with correcting the zero point of the MFC 1, according to an embodiment, it may be verified that the fluid is stopped through the determination that the fluid is not leaking from the main flow path portion 103.

In some examples, operations S210, S220, and S230 may be performed in series such that operation S220 follows operation S210 and operation S230 follows operation S220. In some examples, operations S210, S220, and S230 may be performed in parallel. When it is determined in operation S210 that the fluid is leaking, the operations following operation S210, that is, operation S220 of determining whether the fluid is stabilized, operation S230 of determining whether a difference in the pressure values output by the first pressure sensor 130A and the second pressure sensor 130B is within the normal range, and operation S240 of calculating the zero point calibration value and applying the zero point calibration value to the zero points of the first pressure sensor 130A and the second pressure sensor 130B, may not be performed. That is, the zero point calibration value may not be applied to an existing zero point value when operation determines that fluid is leaking. For example, operation S250 may be performed in which the zero point calibration value is not updated. In this case, the operation of the valves and the pressure sensors may be checked to (operation S260) to determine if they are operating properly. After verifying the operation of the valves and the pressure sensor, the process may return to operation S210 of determining whether the fluid is leaking.

Therefore, through operation S210 of determining whether the fluid is leaking from the main flow path portion 103, it is possible to determine whether the MFC 1, according to an embodiment, is in a state suitable for zero point calibration (e.g., the fluid is not flowing). Through operation S210 of determining whether the fluid is leaking, it is possible to stably and accurately correct the zero point of the MFC 1.

Operation S200 of correcting the zero points of the first pressure sensor 130A and the second pressure sensor 130B may include operation S220 of determining whether the fluid is stabilized in the main flow path portion 103. Determining whether the fluid is stabilized in operation S220 may be based on the pressure values output by the first pressure sensor 130A and the second pressure sensor 130B. It may be determined that the fluid is stabilized when the maximum standard deviation of the pressure values output by the first pressure sensor 130A and the second pressure sensor 130B over a time interval is less that a threshold standard deviation S₂ (e.g., max(std(P₁), std(P₂))≤(δ₂).

As shown in FIG. 6, when the larger of a standard deviation std(P₁) of the pressure value output by the first pressure sensor 130A and a standard deviation std(P₂) of the pressure value output by the second pressure sensor 130B is equal to or less than a predetermined threshold value δ₂, it indicates that variations of the pressure in the main flow portion 130Cas indicated by the pressure values output by the first pressure sensor 130A and the second pressure sensor 130B may be relatively stable. The reference value δ₂ may be determined depending on the facility environment of the MFC 1.

When both the standard deviation std(P₁) of the pressure value output by the first pressure sensor 130A and the standard deviation std(P₂) of the pressure value output by the second pressure sensor 130B are less than or equal to the predetermined threshold value δ₂, the pressure within the main flow path portion 103 as indicated by the pressure values output by the first pressure sensor 130A and the second pressure sensor 130B may be stabilized. Therefore, when both the standard deviation std(P₁) of the pressure values output by the first pressure sensor 130A and the standard deviation std(P₂) of the pressure values output by the second pressure sensor 130B are less than or equal to the predetermined threshold value δ₂, it may be determined that the fluid is stabilized.

When any one of the standard deviation std(P₁) of the pressure values output by the first pressure sensor 130A and the standard deviation std(P₂) of the pressure values output by the second pressure sensor 130B exceeds the predetermined threshold value δ₂, it may be determined that the pressure within the main flow path portion 103 as indicated by the pressure values output by the first pressure sensor 130A and the second pressure sensor 130B are not stable, and in this case, that the fluid is not stabilized.

Therefore, through operation S220 of determining whether the fluid is stabilized, it is possible to determine whether the MFC 1 according to an embodiment is in a state suitable for zero point calibration (e.g., the fluid is stable). Through operation S220 of determining whether the fluid is stabilized, it is possible to stably and accurately correct the zero point of the MFC 1.

In operation S220 of determining whether the fluid is stabilized, when it is determined that the fluid is not stabilized such as by a condition not being satisfied (e.g., the maximum standard deviation exceeds the reference value), the following operation S230 of determining whether the difference in the pressure values output by the first pressure sensor 130A and the second pressure sensor 130B is within a normal range may not be performed and the zero point calibration value may not be updated (operation S250). In this case, a valve or a pressure sensor may be checked (operation S260) to determine if they are operating properly. After verifying the operation of the valves and the pressure sensor, the process may return to operation S210 of determining whether the fluid is leaking.

Operation S200 of correcting the zero points of the first pressure sensor 130A and the second pressure sensor 130B may include operation S230 of determining whether the difference in the pressure values output by the first pressure sensor 130A and the second pressure sensor 130B is within a normal range.

As shown in FIG. 6, when a difference |P₁−P₂| between a pressure value P₁ output by the first pressure sensor 130A and a pressure value P₂ output by the second pressure sensor 130B is less than or equal to a threshold value δ₃ it may indicate that the pressure value P₁ output by the first pressure sensor 130A and the pressure value P₂ output by the second pressure sensor 130B are measuring the same or a similar pressure within a range of the threshold value δ₃ when the valve is closed. In some examples, the first pressure sensor 130A and the second pressure sensor 130B may output the same pressure value when the valve is closed.

Therefore, when the difference |P₁−P₂| between the pressure value P₁ output by the first pressure sensor 130A and the pressure value P₂ output by the second pressure sensor 130B is equal to or less than the threshold value δ₃, it may indicate that the pressure measured by the first pressure sensor 130A and the pressure measured by the second pressure sensor 130B are within the normal range The reference value δ₃ may be determined depending on the facility environment of the MFC 1.

When the difference |P₁−P₂| between the pressure value P₁ output by the first pressure sensor 130A and the pressure value P₂ output by the second pressure sensor 130B exceeds the threshold value δ₃, it may indicate that the pressure value P₁ measured by the first pressure sensor 130A and the pressure measured by the second pressure sensor 130B exceeds the normal range.

Therefore, through operation S230 of determining whether the difference in the pressure values output by the first pressure sensor 130A and the second pressure sensor 130B is within the normal range, it is possible to determine whether the MFC 1 according to an embodiment is in a state suitable for zero point calibration. Through operation S230 of determining whether the difference in the pressure values output by the first pressure sensor 130A and the second pressure sensor 130B is within the normal range, it is possible to stably and accurately correct the zero point of the MFC 1.

In operation S230 of determining whether the difference in the pressure values output by the first pressure sensor 130A and the second pressure sensor 130B is within the normal range, when it is determined that the difference in pressure values is greater than the threshold value, operation S240 of calculating the zero point calibration value and applying the zero point calibration value to the zero points of the first pressure sensor 130A and the second pressure sensor 130B may not be performed. For example, the zero point calibration value may not be updated (operation S250). In this case, operation S260 may be performed in which the valve and the pressure sensor may be checked and the process may return to operation S210 of determining whether the fluid is leaking.

After operation S230 of determining whether the difference in the pressure values output by the first pressure sensor 130A and the second pressure sensor 130B is within the normal range, operation S240 of calculating the zero point calibration value based on the pressure values output by the first pressure sensor 130A and the second pressure sensor 130B and applying the zero point calibration value to the zero points of the first pressure sensor 130A and the second pressure sensor 130B may be performed. The zero point calibration value may be obtained with respect to each of the zero point of the first pressure sensor 130A and the zero point of the second pressure sensor 130B.

The zero point calibration value may be dependent on a power-on time tₚ (e.g., a duration that the MFC 1 has been powered on). The zero point of a pressure sensor may experience an internal distortion that changes dependent on the power-on time tₚ. The power-on time tₚ may be correlated with the internal distortion of the zero point. Therefore, the zero point calibration value may have a linear relationship with the power-on time tₚ since the current zero point of the pressure sensor was set (e.g., since the previous zero point calibration).

In addition, the zero point calibration value may be dependent on a flow-on time t_{f} (e.g., a duration that the MFC 1 has been used for flow control). The zero point of a pressure sensor may experience an external distortion that changes dependent on the flow-on time. The flow-on time t_{f} may be correlated with the external distortion of the zero point. Therefore, the zero point calibration value may have a linear correlation with the flow-on time t_{f} since the current zero point of the pressure sensor was set (e.g., since the previous zero point calibration).

The relationship between the zero point calibration value, the power-on time tₚ, and the flow-on time tₚ may be estimated with a multiple linear regression model as shown in Equation 1 below. Here, a subscript ‘i’ denotes a value of an i-th period, ‘i−1’ denotes a period before the i-th period, and ‘i−2’ denotes a period before the i−1th period. Each period may correspond to a period of time between time points when a periodic maintenance (PM) is performed (i.e., zero point calibration time point).

z(i) denotes a zero point value of a pressure sensor during the i-th period, and Δz(i) denotes a zero point calibration value that was used to update the zero point value of the pressure sensor at the start of the i-th period. tₚ(i) denotes a timestamp value of a power-on time of the i-th period (i.e., the duration of the power supply time between the i−1th period and the i-th period). t_{f} (i) denotes a timestamp value of a flow-on time of the i-th period (i.e., the duration of the fluid supply time between the i−1th period and the i-th period). α denotes a model estimation coefficient of tₚ(i), and β denotes a model estimation coefficient of t t_{f}(i).

$$Δ z ( i ) = ( z ( i ) - z ( i - 1 ) ) = α \cdot {t}_{p} ( i - 1 ) + β \cdot {t}_{f} ( i - 1 ) \qquad [ Equation 1 ]$$

The model estimation coefficients α and β in Equation 1 above may be obtained by simultaneously combining Δz(i) and Δz(i−1) as shown in Equation 2 below by using i-th and i−1th zero point calibration results.

$$\{ \begin{matrix}Δ z ( i ) = ( z ( i ) - z ( i - 1 ) ) = α \cdot {t}_{p} ( i - 1 ) + β \cdot {t}_{f} ( i - 1 ) \\ Δ z ( i - 1 ) = ( z ( i - 1 ) - z ( i - 2 ) ) = α \cdot {t}_{p} ( i - 2 ) + \cdot {t}_{f} ( i - 2 )\end{matrix} \qquad [ Equation 2 ]$$

Referring to FIG. 6, the model estimation coefficients of Δz(i) and of Δz(i−1) in Equation 1 above may be obtained as in Equation 3 below by simultaneously combining α and β in Equation 2 above. Here, it may be assumed that a model estimation coefficient α(i) with respect to the timestamp value tₚ(i) of the power-on time of the i-th period and a model estimation coefficient α(i−1) with respect to the timestamp value tₚ(i−1) of the power-on time of the i−1th period are approximately the same (e.g., the relationship between Δz and t_{P} is linear. Also, here, it may be assumed that a model estimation coefficient β(i) with respect to the timestamp value t_{f} (i) of the flow-on time of the i-th period and a model estimation coefficient β(i−1) with respect to the timestamp value t_{f}(i−1) of the flow-on time of the i−1th period are approximately the same (e.g., the relationship between Δz and t_{f} is linear.

$$α = \frac{{t}_{f} ( i - 1 ) Δ z ( i - 1 ) - {t}_{f} ( i - 2 ) Δ z ( i )}{{t}_{f} ( i - 1 ) {t}_{p} ( i - 2 ) - {t}_{f} ( i - 2 ) {t}_{p} ( i - 1 )} ≅ α ( i ) ≅ α ( i - 1 ) \qquad [ Equation 3 ]$$

$$β = \frac{{t}_{p} ( i - 1 ) Δ z ( i - 1 ) - {t}_{p} ( i - 2 ) Δ z ( i )}{{t}_{p} ( i - 1 ) {t}_{f} ( i - 2 ) - {t}_{p} ( i - 2 ) {t}_{f} ( i - 1 )} ≅ β ( i ) ≅ β ( i - 1 )$$

The model estimation coefficients α(i) and β(i) of the i-th period may be obtained by using the timestamp value tₚ(i−1) of the power-on time of the i−1th period, a timestamp value tₚ(i−2) of a power-on time of an i−2th period, the timestamp value t_{f}(i−1) of the flow-on time of the i−1th period, a timestamp value t_{f}(i−2) of a flow-on time of the i−2th period, the zero point calibration value Δz(i) of the i-th period, and the zero point calibration value Δz(i−1) of the i−1th period.

For example, the model estimation coefficients α(i) and β(i), which may be used to calculate a new zero calibration value using the formula α(i)tₚ(i)+β(i)t_{f}(i), may be obtained by using the two most recently used zero point calibration values Δz(i) and Δz(i−1). For example, in the case of i=2, after a regular facility maintenance is performed twice (e.g., a calibration of a pressure sensor), Δz(2) and Δz(1) values that were used to update the zero point of the pressure sensor may be obtained, model estimation coefficients α α(2) and β(2) may be calculated based on Δz(2) and Δz(1), and the zero point may be corrected using the new zero calibration value calculated from Δz(2), Δz(1), tₚ(i), and tₚ(i). Alternatively, the model estimation coefficients α(i) and β(i) for obtaining the new zero calibration value Δz(i−2) may be obtained by using three or more zero point calibration values Δz(i), Δz(i−1), Δz(i−2), . . . .

A new zero point \hat{z}(tₚ(i), t_{f}(i)) of a pressure sensor may be obtained as in Equation 4 below by using the model estimation coefficients α(i) and β(i) of Equation 3 above.

$$\hat{z} ( {t}_{p} ( i ) , {t}_{f} ( i ) = z ( i ) + α ( i ) {t}_{p} ( i ) + β ( i ) {t}_{f} ( i ) \qquad [ Equation 4 ]$$

In other words, a new zero calibration value Δz(tₚ(i), t_{f}(i)) may be calculated by adding a value obtained by multiplying the power on time tₚ(i) during which power was supplied to the MFC 1 by α(i) to a value obtained by multiplying the flow on time t_{f}(i) during which a flow was supplied to the MFC 1 by β(i), and the new zero point \hat{z}(t_{P} (i), t_{f} (i)) may be obtained by adding the new zero calibration value Δz(t_{P} (i), t_{f}(i)) to the current zero point z(i).

α(i) and β(i) may be obtained by using the power on time tₚ(i) at which power was supplied to the MFC 1 and the flow on time t_{f}(i) at which a flow was supplied to the MFC 1 in a first period i, the power on time tₚ (i−1) at which power was supplied to the MFC 1 and the flow on time t_{f}(i−1) at which flow was supplied to the MFC 1 in a second period i−1, the zero point calibration value Δz(i−1) for the second period i−1, and the zero point calibration value Δz(i−2) for a third period i−2.

The new zero point \hat{z} (i) may be obtained with respect to each of a zero point [symbol] (i) of the first pressure sensor 130A and a zero point [symbol] (i) of the second pressure sensor 130B. That is, the model estimation coefficients α₁, β₁ and α₂, β₂ may be obtained, respectively, with respect to the multiple linear regression model Δz₁(i)=α₁·tₚ(i−1)+β₁·t_{f}(i−1) of the first pressure sensor 130A and the multiple linear regression model Δz₂(i)=α₂·tₚ (i−1)+β₂·t_{f} (i−1) of the second pressure sensor 130B. Accordingly, new zero points \hat{z}₁ (tₚ(i), t_{f} (i)) and \hat{z}₂ (tₚ (i), t_{f}(i)) of the first pressure sensor 130A and the pressure sensor 130B may be obtained, respectively.

To this end, the MFC 1 may obtain the zero points of the first pressure sensor 130A and the second pressure sensor 130B during a zero point calibration operation and obtain the timestamps of the power-on time t_{P} and the flow-on time t_{f}.

In operation S240 of calculating the zero point calibration value and applying the zero point calibration value to the zero points of the first pressure sensor 130A and the second pressure sensor 130B, the zero point calibration value may be applied by applying an independently (e.g., a separate signal for each pressure sensor) generated electrical signal (e.g., the drift signals in FIG. 8) to each of the first pressure sensor 130A and the second pressure sensor 130B.

After operation S240 of calculating the zero point calibration value and applying the zero point calibration value to the zero points of the first pressure sensor 130A and the second pressure sensor 130B is performed, the zero point calibration method used by the MFC 1 according to an embodiment may end.

Using the disclosed zero point calibration method to update the zero points of the first pressure sensor 130A and the second pressure sensor 130B of the MFC 1, a zero point calibration may be performed by considering the surrounding environment of the MFC 1, the state of the fluid, and the state of the flow of the fluid. Additionally, once the preceding zero point calibration method has been performed at least two times and the model coefficients determined, additional zero point calibrations may be performed between servicing of the MFC 1 such as a part of a manufacturing process. The zero-point calibration may be performed while a manufacturing device is operating without requiring the manufacturing device to be taken offline (e.g., stopping the flow of the fluid in the MFC 1). For example, zero point calibration values can be calculated while the manufacturing device is online from the power-on time, the flow-on time of the pressure sensors, and the model coefficients without stopping the fluid flow, and the calculated zero point calibration value can be applied to each pressure sensor. The MFC 1 may use the updated zero point to continue providing a controlled flow of gas to the manufacturing process, which may include adjusting the opening of the valves to regulate the controlled amount of gas flowing to the manufacturing process in view of fluctuations in the upstream delivery of the gas. Because zero point calibration is improved as described above, the flow of a fluid supplied to a semiconductor manufacturing devices may be more precisely controlled through the MFC 1, and thus, the quality of a process resultant may be improved. Additionally, automation of a zero point calibration may reduce manpower input and improve process time.

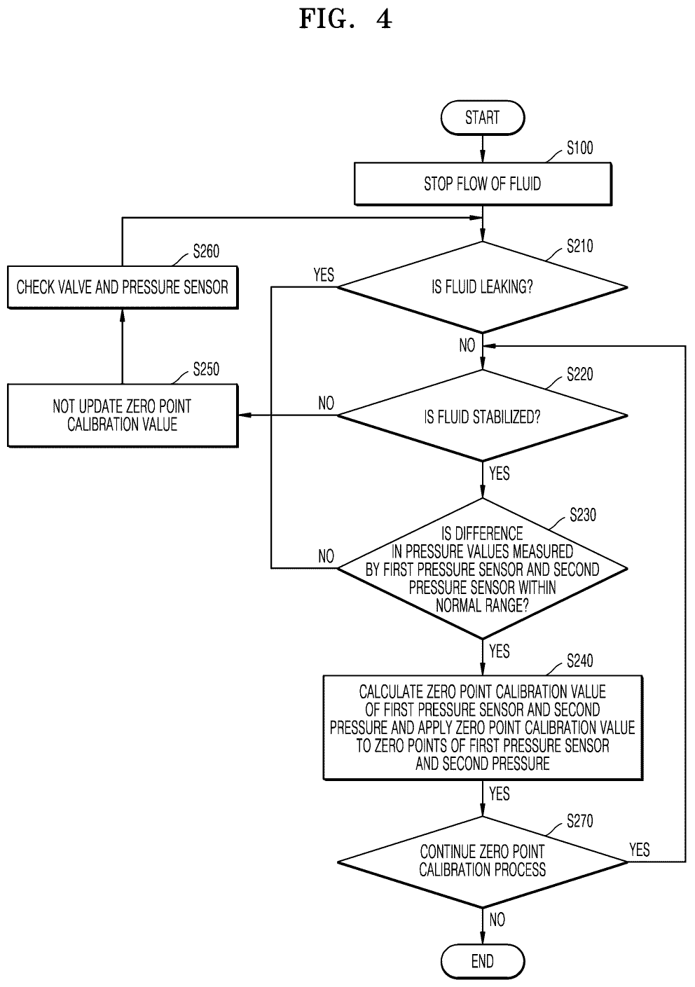

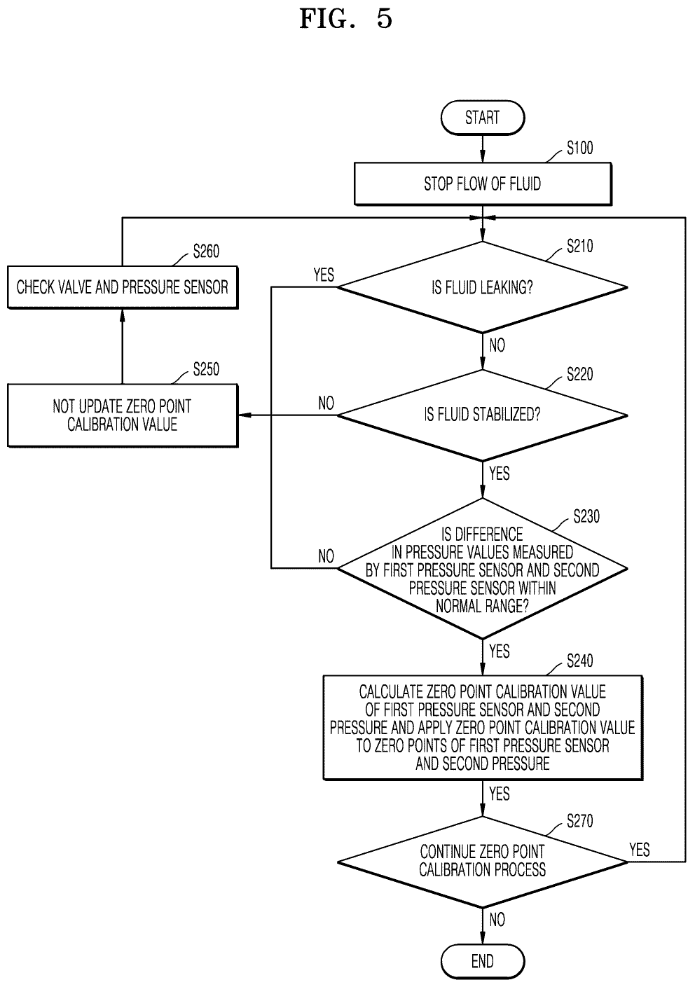

FIG. 4 is a flowchart illustrating a zero point calibration method for the first and second pressure sensors 130A and 130B of the MFC 1 according to an embodiment. FIG. 5 is a flowchart illustrating a zero point calibration method for the first and second pressure sensors 130A and 130B of the MFC 1 according to an embodiment. Descriptions of elements that may be redundant with those described previously may be omitted.

Referring to FIGS. 4 and 5, after operation S240 of calculating the zero point calibration value and applying the zero point calibration value to the zero points of the first pressure sensor 130A and the second pressure sensor 130B, the zero point calibration method may further include operation S270 of determining whether to continue a zero point calibration process.

In an embodiment, the zero points of the first pressure sensor 130A and the second pressure sensor 130B of the MFC 1 according to an embodiment may be repeatedly corrected to more accurately correct the zero points of the first pressure sensor 130A and the second pressure sensor 130B of the MFC 1. A user and/or the controller 200 of the MFC 1 according to an embodiment may continue the zero point calibration process.

As shown in FIG. 4, in operation S270 of determining whether to continue zero point calibration, when it is determined to continue the zero point calibration process, the zero point calibration process may be performed again returning to operation S220 of determining whether the fluid is stabilized, which is the next operation in operation S210 of determining whether the fluid is leaking.

In some embodiments, after the zero point calibration process is completed at least two time and the model coefficients are found, further updates to the zero point of each of the pressure sensors may be performed using the model coefficients, the power-on time, and the flow-on time. The further updates may be performed between service intervals at which time the zero point calibration method may be performed. Thus, the zero point of the pressure sensors may be corrected between service intervals.

Alternatively, as shown in FIG. 5, in operation S270 of determining whether to continue the zero point calibration process, when it is determined to continue the zero point calibration process, the zero point calibration process may be performed again from operation S210 of determining whether the fluid is leaking.

FIG. 6 is a flowchart illustrating a zero point calibration method of the first and second pressure sensors 130A and 130B of the MFC 1 according to an embodiment. FIG. 6 has been described in detail with reference to FIGS. 3 to 5, and further description is omitted.

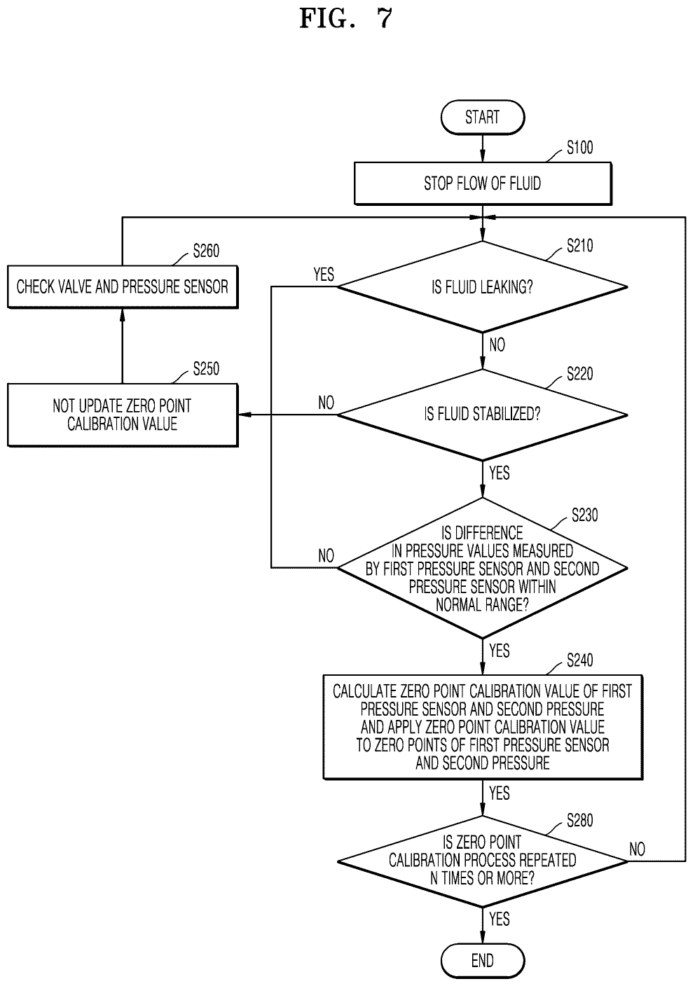

FIG. 7 is a flowchart illustrating a zero point calibration method of the first and second pressure sensors 130A and 130B of the MFC 1 according to an embodiment. Descriptions of elements described previously may be omitted while new or changed elements may be described in further detail.

The embodiment illustrated in FIG. 7 is similar to the embodiment illustrated in FIG. 5, with the exception that operation S270 of determining whether to continue a zero point calibration process as described in relation to FIG. 7 may be replaced with operation S280 of determining whether the zero point calibration process has been repeated N times (where N is a natural number of 1 or more).

When zero point calibration is performed a sufficient number of times, the zero point calibration method of the first pressure sensor 130A and the second pressure sensor 130B may automatically end. As described above, the start, the zero point calibration, and the end of the zero point calibration method of the first pressure sensor 130A and the second pressure sensor 130B of the MFC 1 according to an embodiment may all be automated.

FIG. 8 is a graph illustrating a simulation to experimentally perform a zero point calibration method used by the MFC 1 according to an embodiment.

Referring to FIG. 8, the horizontal axis represents time (month), and the vertical axis represents a drift rate (% Fullscale) of a pressure sensor. An intrinsic drift may occur due to bending of a diaphragm over time, and an extrinsic drift may occur due to external use at a greater level. An example of the waveform of a virtual total drift signal generated by simulating a situation in which the internal drift and the external drift occur together in the MFC 1 according to an embodiment may be shown in FIG. 8.

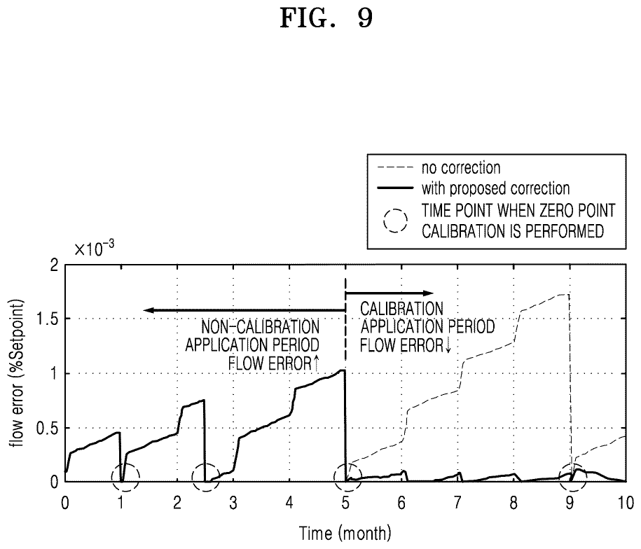

FIG. 9 is a graph illustrating results of applying a zero point calibration method used by the MFC 1 to a facility according to an embodiment.

Referring to FIG. 9, the horizontal axis represents time (month), and the vertical axis represents a flow error that occurs in the MFC 1 when a zero point of a pressure sensor of the MFC 1 is distorted. A dotted circle may indicate the time at which calibration of the MFC 1 is performed according to a facility manual. It may be seen that before applying the zero point calibration method used by the MFC 1 according to an embodiment (a non-calibration application period), the flow error increases with the passage of time and use, but is normalized at the time of calibration (the dotted circle).

On the other hand, it may be seen that after applying the zero point calibration method used by the MFC 1 according to an embodiment (a calibration application period) and applying calculated zero point calibration values between zero point calibration times, the flow error is significantly reduced even outside the calibration period (the dotted circle) compared to when the zero point calibration method is not applied (the dotted line).

After zero point calibration continues by applying the zero point calibration method used by the MFC 1 according to an embodiment, a flow error value close to 0 is observed as shown in FIG. 9.

The zero point calibration method for the MFC 1 according to an embodiment may reduce a zero point calibration error caused of a flow sensor due to aging of the flow sensor over time or a change in the external environment. That is, before calculating the zero point calibration value, it is determined whether the fluid is stabilized and whether the pressure sensor is normal, and a new zero point calibration value is calculated by considering internal and external factors based on the power-on time, the flow-on time, and the recent two or more zero point calibration results of the pressure sensor, and thus, zero point calibration may be performed by considering the state of the fluid.

Because zero point calibration is improved according to the inventive concept, the flow of fluid to be supplied to processing devices may be more precisely controlled through the MFC 1, and thus, the quality of process resultants may be improved. In addition, through automation of zero point calibration, manpower input during manual zero point calibration may be reduced, and thus, the process time may be improved.

While the inventive concept has been particularly shown and described with reference to embodiments thereof, it will be understood that various changes in form and details may be made therein without departing from the spirit and scope of the following claims.

What is claimed is:

1. A method of manufacturing using a mass flow controller (MFC), comprising:
closing a valve installed in a flow path of the MFC to prevent a fluid from flowing therein due to a closure of the flow path by the valve;
determining that the fluid is not leaking based on a first pressure value output by a first pressure sensor provided in the flow path and a second pressure value output by a second pressure sensor provided in the flow path;
determining that the fluid is stabilized based on the first pressure value and the second pressure value;
determining that the first pressure sensor and the second pressure sensor are normal based on a difference between the first pressure value and the second pressure value;
calculating a first zero point calibration value for the first pressure sensor and a second zero point calibration value for the second pressure sensor, the calculating based on a first zero point of the first pressure sensor and a second zero point of the second pressure sensor, a time when power is supplied to the MFC, and a time when a flow is supplied to the MFC;
applying the first zero point calibration value to a zero point of the first pressure sensor and the second zero point calibration value to a zero point of the second pressure sensor; and
measuring the mass flow rate through the flow path with the first pressure sensor and the second pressure sensor and adjusting the valve based on the mass flow rate to regulate the flow of the fluid to a manufacturing device.

2. The method of manufacturing of claim 1, wherein determining that the fluid is not leaking includes determining that a rate of change of the first pressure value over time and a rate of change of the second pressure value over time are less than a predetermined threshold value.

3. The method of manufacturing of claim 1, wherein the determining that the fluid is stabilized includes determining that a standard deviation of a first plurality of pressure values including the first pressure value and a standard deviation of a second plurality of pressure values include the second pressure value are less than a predetermined threshold value.

4. The method of manufacturing of claim 1, wherein the calculating of the zero point calibration value includes calculating the zero point calibration value by adding a value obtained by multiplying a length of time when the power is supplied to the MFC by a first coefficient to a value obtained by multiplying a second length of time when the flow is supplied to the MFC by a second coefficient.

5. The method of manufacturing of claim 4, wherein the first coefficient and the second coefficient are determined by using a time when the power is supplied to the MFC and a time when the flow is supplied to the MFC in a first period, and a time when the power is supplied to the MFC and a time when the flow is supplied to the MFC in a second period.

6. The method of manufacturing of claim 4, wherein the first coefficient and the second coefficient are obtained by using a zero point calibration value of each of the first pressure sensor and the second pressure sensor output in a first period, and a zero point calibration value of each of the first pressure sensor and the second pressure sensor output in a second period.

7. The method of manufacturing of claim 4, wherein the first coefficient and the second coefficient are obtained with respect to a first period, a second period before the first period, and a third period before the second period by using a zero point calibration value of each of the first pressure sensor and the second pressure sensor output in the first period, a zero point calibration value of each of the first pressure sensor and the second pressure sensor output in the second period, a time when the power is supplied to the MFC and a time when the flow is supplied to the MFC in the second period, and a time when the power is supplied to the MFC and a time when the flow is supplied to the MFC in the third period.

8. The method of manufacturing of claim 1, wherein,
an initial determination is made that the fluid is leaking, the fluid is not stabilized, or an initial first pressure value and an initial second pressure value are beyond a normal range before determining that the fluid is not leaking.

9. The method of manufacturing of claim 1, wherein after the applying the zero point calibration value to the zero point of each of the first pressure sensor and the second pressure sensor, a zero point calibration is repeated from the determining whether the fluid is leaking.

10. The method of manufacturing of claim 9, wherein after the applying the zero point calibration value to the zero point of each of the first pressure sensor and the second pressure sensor, in the applying the zero point calibration value, when a number of times the zero point calibration value has been applied to the zero point of each of the first pressure sensor and the second pressure sensor is N times or more (N is a natural number of 1 or more), the zero point calibration ends.

11. A method of manufacturing a semiconductor device using a mass flow controller (MFC), the method comprising:
closing a valve installed in a flow path of the MFC to prevent a fluid from flowing therein due to a closure of the valve;
determining that the fluid is not leaking by determining that a rate of change of a first pressure value over time and a rate of change of a second pressure value over time are less than or equal to a predetermined threshold value, based on the first pressure value output by a first pressure sensor provided in the flow path and the second pressure value output by a second pressure sensor provided in the flow path;
determining that the fluid is stabilized by determining that a standard deviation of the first pressure value and a standard deviation of the second pressure value are less than or equal to a predetermined threshold value based on the first pressure value and the second pressure value;
determining whether the first pressure sensor and the second pressure sensor are normal based on a difference between the first pressure value and the second pressure value;
calculating a first zero point calibration value for the first pressure sensor and a second zero point calibration value for the second pressure sensor; and
applying the first zero point calibration value to a zero point of the first pressure sensor and the second zero point calibration value to the second pressure sensor, and
measuring the mass flow rate through the flow path with the first pressure sensor and the second pressure sensor and adjusting the valve based on the mass flow rate to regulate the flow of the fluid to a manufacturing device.

12. The method of manufacturing of claim 11, wherein the calculating the first zero point calibration value includes calculating the first zero point calibration value based on the zero point of the first pressure sensor, a time when power is supplied to the MFC, and a time when a flow is supplied to the MFC and the calculating the second zero point calibration value includes calculating the second zero point calibration value based on the zero point of the second pressure sensor, a time when power is supplied to the MFC, and a time when a flow is supplied to the MFC.

13. The method of manufacturing of claim 12, wherein the calculating of the first zero point calibration value includes calculating the first zero point calibration value by adding a value obtained by multiplying the time when the power is supplied to the MFC by a first coefficient to a value obtained by multiplying the time when the flow is supplied to the MFC by a second coefficient.

14. The method of manufacturing of claim 13, wherein the first coefficient and the second coefficient are obtained by using a time when the power is supplied to the MFC and a time when the flow is supplied to the MFC in a first period, and a time when the power is supplied to the MFC and a time when the flow is supplied to the MFC in a second period.

15. The method of manufacturing of claim 13, wherein the first coefficient and the second coefficient are obtained by using a zero point calibration value of the first pressure sensor in a first period, and a zero point calibration value of the first pressure sensor in a second period.

16. The method of manufacturing of claim 13, wherein the first coefficient and the second coefficient are obtained, with respect to a first period, a second period before the first period, and a third period before the second period, by using a zero point calibration value of the first pressure sensor in the first period, a zero point calibration value of each of the first pressure sensor in the second period, a time when the power is supplied to the MFC and a time when the flow is supplied to the MFC in the second period, and a time when the power is supplied to the MFC and a time when the flow is supplied to the MFC in the third period.

17. A method of manufacturing a semiconductor device using a mass flow controller (MFC), comprising:
closing a valve installed in a flow path of the MFC to prevent a fluid from flowing therein due to a closure of the flow path;
determining that the fluid is not leaking by determining that a change rate of each of a first pressure value and a second pressure value over time are less than or equal to a predetermined threshold value, based on the first pressure value output by a first pressure sensor provided in the flow path and the second pressure value output by a second pressure sensor provided in the flow path;
determining that the fluid is stabilized by determining that a standard deviation of the first pressure value and a standard deviation of the second pressure value are less than or equal to a predetermined threshold value;
determining whether the first pressure sensor and the second pressure sensor are normal by determining whether a difference between the first pressure value and the second pressure value is less than or equal to a predetermined threshold value;
calculating a respective zero point calibration value of each of the first pressure sensor and the second pressure sensor based on a respective zero point of each of the first pressure sensor and the second pressure sensor, a time when power is supplied to the MFC, and a time when a flow is supplied to the MFC;
applying the respective zero point calibration value to the respective zero point of each of the first pressure sensor and the second pressure sensor; and
measuring the mass flow rate through the flow path with the first pressure sensor and the second pressure sensor and adjusting the valve based on the mass flow rate to regulate the flow of the fluid to a manufacturing device,
wherein the respective zero point calibration value is obtained by adding a value obtained by multiplying the time when the power is supplied to the MFC by a respective first coefficient to a value obtained by multiplying the time when the flow is supplied to the MFC by a respective second coefficient, and
after applying the zero point calibration value, a zero point calibration is repeated from the determining that the fluid is not leaking, and, when a number of times the respective zero point calibration value has been applied is N times or more (N is a natural number of 1 or more) in the applying of the respective zero point calibration value, the zero point calibration ends.

18. The method of manufacturing of claim 17, wherein the respective first coefficient and the respective second coefficient are obtained by using a time when the power is supplied to the MFC and a time when the flow is supplied to the MFC in a first period, and a time when the power is supplied to the MFC and a time when the flow is supplied to the MFC in a second period.

19. The method of manufacturing of claim 17, wherein the respective first coefficient and the respective second coefficient are obtained by using a respective zero point calibration value of each of the first pressure sensor and the second pressure sensor in a first period, and a respective zero point calibration value of each of the first pressure sensor and the second pressure sensor in a second period.

20. The method of manufacturing of claim 17, wherein the respective first coefficient and the respective second coefficient are obtained with respect to a first period, a second period before the first period, and a third period before the second period by using a respective zero point calibration value of each of the first pressure sensor and the second pressure sensor in the first period, a respective zero point calibration value of each of the first pressure sensor and the second pressure sensor in the second period, a time when the power is supplied to the MFC and a time when the flow is supplied to the MFC in the second period, and a time when the power is supplied to the MFC and a time when the flow is supplied to the MFC in the third period.
